(19) United States
(12) Patent Application Publication
(10) Pub. No.: US 2026/0059793 A1
(43) Pub. Date: Feb. 26, 2026

(54) OXIDE SEMICONDUCTOR DEVICES WITH TUNING MATERIALS

(71) Applicant: ZINITE CORPORATION, Edmonton (CA)

(72) Inventors: Alex MA, Edmonton (CA); Gem SHOUTE, Edmonton (CA)

(21) Appl. No.: 19/299,145

(22) Filed: Aug. 13, 2025

Related U.S. Application Data
(60) Provisional application No. 63/685,379, filed on Aug. 21, 2024.

(51) Int. Cl. H10D 30/67; H10D 30/01

(52) U.S. Cl. CPC H10D 30/6704; H10D 30/0314; H10D 30/6731; H10D 30/6755

(57) ABSTRACT

In a thin-film transistor, a body of tuning material is provided between a substrate and a body of channel material. The body of tuning material removes undesirable chemical species from the body of channel material, a body of gate dielectric material, or both the body of channel material and the body of gate dielectric material. A body of blocking material may be provided to inhibit such tuning that may be caused by a body of gate material.

### CROSS-REFERENCE TO RELATED APPLICATIONS

This application claims priority to and the benefit of U.S. provisional application Ser. No. 63/685,379, filed Aug. 21, 2024, which is incorporated herein by reference in its entirety.

### FIELD

This application relates to thin-film semiconductor devices, such as thin-film transistors, and methods of making same.

### BACKGROUND

Semiconductor devices with oxide semiconductor channels, such as complementary metal-oxide-semiconductor (CMOS) transistors, thin-film transistors (TFTs), etc., are well known. As such devices are widely employed in a variety of use cases with differing needs, a variety of oxide semiconductor channel stacks are used in these devices and a variety of manufacturing processes are known to produce them.

With at least some of these semiconductor devices, the current carrying capacity of the oxide semiconductor channel stack is a limiting factor in the performance of circuits employing the semiconductor devices. Undesirable chemical species present in the channel stack may reduce current carrying capacity and/or the useful operational life of the device.

### SUMMARY

According to an aspect of the present disclosure, a thin-film transistor includes a substrate, a source including a body of source material over the substrate, a drain including a body of drain material over the substrate, and a body of channel material between the source and the drain. The channel material is an oxide semiconductor. The thin-film transistor further includes a body of gate dielectric material on the body of channel material, a body of gate material on the body of gate dielectric material, and a body of tuning material between the substrate and the body of channel material. The body of tuning material removes undesirable chemical species from the body of channel material, the body of gate dielectric material, or both the body of channel material and the body of gate dielectric material.

The thin-film transistor may further include a body of dielectric mediating material between the body of tuning material and the body of channel material.

The body of tuning material may be in electrical contact with the body of source material.

The thin-film transistor may further include a second body of tuning material in electrical contact with the body of drain material.

The thin-film transistor may further include a body of blocking material to inhibit tuning by the body of gate material.

The body of blocking material may be positioned between the body of gate dielectric material and the body of gate material.

The body of blocking material may be positioned between the body of channel material and the body of gate dielectric material.

The body of blocking material may extend an entire length of the body of channel material.

The thin-film transistor may further include a second body of blocking material positioned at a location different from the body of blocking material to inhibit tuning by the body of gate material.

The body of blocking material may include a plasma treated portion of the body of gate dielectric material.

The body of blocking material may include a plasma treated portion of the body of channel material.

The body of blocking material may be positioned at a location where the body of channel material is closer to the body of gate material than to the body of tuning material.

The undesirable chemical species may include oxygen.

The tuning material may be titanium.

According to an aspect of the present disclosure, a method of manufacturing a thin-film transistor includes forming a body of tuning material over a substrate, forming a source including a body of source material over the body of tuning material, forming a drain including a body of drain material over the body of tuning material, and forming a body of channel material between the source and the drain. The channel material is an oxide semiconductor. The method further includes forming a body of gate dielectric material on the body of channel material and forming a body of gate material on the body of gate dielectric material. The body of tuning material removes undesirable chemical species from the body of channel material, the body of gate dielectric material, or both the body of channel material and the body of gate dielectric material.

The method may further include forming a body of dielectric mediating material on the body of tuning material.

The method may further include forming a body of blocking material to inhibit tuning by the body of gate material.

The method may further include forming multiple bodies of blocking material to inhibit tuning of multiple regions of the body of channel material, the body of gate dielectric material, or both the body of channel material and the body of gate dielectric material.

The undesirable chemical species may include oxygen.

The tuning material may be titanium.

### BRIEF DESCRIPTION OF THE FIGURES

FIG. 1 is a cross-sectional view of an example thin-film transistor with tuning material according to the present disclosure.

FIG. 2A is a cross-sectional view of an example thin-film transistor with tuning material and blocking material according to the present disclosure.

FIG. 2B is a cross-sectional view of another example thin-film transistor with tuning material and selectively positioned blocking material according to the present disclosure.

FIG. 2C is a cross-sectional view of another example thin-film transistor with tuning material and blocking material according to the present disclosure.

FIG. 2D is a cross-sectional view of another example thin-film transistor with tuning material and selectively positioned blocking material according to the present disclosure.

FIG. 3 is a cross-sectional view of an example thin-film transistor with tuning material used as conductors according to the present disclosure.

FIG. 4 is a cross-sectional view of an example stack of thin-film transistors with tuning material according to the present disclosure.

FIG. 5 is a cross-sectional view of an example stack of thin-film transistors with tuning material and electrical connections according to the present disclosure.

### DETAILED DESCRIPTION

The present disclosure relates to tuning one or more materials of a thin-film transistor, such as a metal-oxide semiconductor and/or a metal-oxide dielectric, to reduce or eliminate detrimental effects to the material caused by the presence of undesirable chemical species, such as surplus atoms/elements, contaminates, and/or other undesirable materials. The techniques discussed herein relate to a tuning material that is operable to collect, draw out, and/or immobilize such undesirable species, particularly from dielectric material or semiconductor material. In some examples, a tuning material may be referred to as a getter or gettering material and its function may be referred to as gettering. The tuning material may additionally or alternatively act to divert or block undesirable species from entering the protected material from the outside the device. Blocking material may be provided to focus the tuning effect on a certain region of a material. Tuning may occur when the device is manufactured and/or as the device is operated. Accordingly, dielectric material characteristics, such as dielectric constant and permittivity, and/or oxide semiconductor characteristics, such as current carrying capacity and useful operational life, may be improved in terms of, for example, stability and reliability. These and other aspects and advantages of the present disclosure will be discussed in greater detail below.

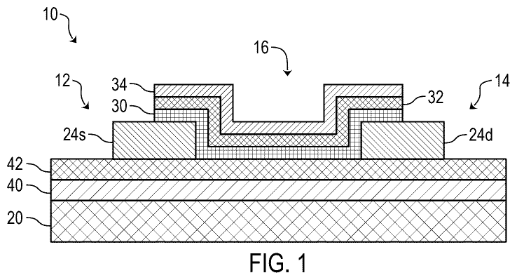

FIG. 1 shows an example thin-film transistor (TFT) 10 according to the present disclosure. The TFT 10 includes a source 12, drain 14, and gate 16.

The TFT 10 is formed with a substrate 20. The substrate 20 may be a silicon wafer, an interlayer dielectric (ILD) layer, an isolation layer, or another type of base layer or substrate. The TFT 10 may be formed in a layer of a stack over another layer of devices, such as TFTs, whether manufactured in accordance with the present disclosure or by another technique, or complementary metal-oxide-semiconductor (CMOS) devices or other front end of line (FEOL) devices. The TFT 10 may be manufactured using extended front-end-of-line (xFEOL), middle-end-of-line (MEOL), back-end-of-line (BEOL), and/or back-side (BSide) processes.

Examples of substrates 20 include silicon dioxide (SiO₂); carbon doped oxide (CDO); silicon nitride; glass; organic polymers such as perfluorocyclobutane or polytetrafluoroethylene; fluorosilicate glass (FSG); organosilicates such as silsesquioxane, siloxane, organosilicate glass; flexible polymers; plastic; a silicon wafer whose surface is processed with wet thermal oxide (WTO) or similar treatment; etc.

The source 12 is formed of a body of source material 24s. Examples of source materials include various metals or other conductors, such as nickel, tungsten, ruthenium, molybdenum, copper, cobalt, titanium nitride, etc. Further examples of source materials include heavily doped n-type materials, degenerate n-type silicon, and III-V compound semiconductors with high conductivity with predominately n-type or electron transport.

The drain 14 is formed of a body of drain material 24d and has the same or similar material and/or structure as the source 12. In other examples, the drain 14 has a material and/or structure different to the source 12.

The TFT 10 further includes a body of channel material 30 disposed between the source 12 and drain 14. The channel material 30 is an oxide semiconductor and is preferably an p-type or n-type metal oxide semiconductor. Examples of suitable oxide semiconductor materials include zinc oxide, tin oxide, indium gallium zinc oxide (IGZO), etc. In this example, the channel material 30 is disposed partially over the bodies of source and drain material 24s, 24d and between the bodies of source and drain material 24s, 24d. In this example, channel material 30 is thin-film oxide semiconductor with a thickness of about 3 nm to about 10 nm.

The TFT 10 further includes a body of gate dielectric material 32 disposed over the channel material 30 and a body of gate material 34 disposed over the gate dielectric material 32. The gate dielectric material 32 may be formed of a high-K dielectric, such as hafnium oxide. Other examples of gate dielectric materials 32 include, without limitation, silicon dioxide, silicon nitride, zirconium oxide, and aluminum oxide. The gate material 34 is a conductor and may be any suitable gate material including, without limitation, tungsten, titanium, titanium nitride, molybdenum, gold, platinum, aluminum, nickel, copper, chromium, hafnium, indium, manganese, iron, vanadium, zinc, tantalum, or combinations/alloys thereof.

In operation, when a voltage is applied between the source 12 and drain 14, and when a suitable voltage is applied to the gate 16, a carrier channel forms in the body of oxide semiconductor channel material 30, which causes flow of current between the source 12 to the drain 14.

The TFT 10 further includes a body of tuning material 40. In this example, the body of tuning material 40 is a layer that is positioned between the substrate 20 and the body of channel material 30. Thus, in the orientation depicted, the body of tuning material 40 is below the body of channel material 30. The body of tuning material 40 may be disposed on the substrate 20 and may be in contact with the substrate 20. Alternatively, an adhesion layer, such as a layer of titanium nitride, may be provided to the substrate 20 to promote adhesion of the body of tuning material 40 to the substrate 20, in which case the body of tuning material 40 is not necessarily in direct contact with the substrate 20.

It should be noted that that the body of tuning material 40 is below the body of channel material 30 in the orientation depicted. However, it should be understood that, if the TFT 10 is flipped upside down, then the body of tuning material 40 would be above the body of channel material 30. The present disclosure is not limited to a particular orientation. A device containing the TFT 10 may have any orientation. Different layers of TFTs in the same device may have the same or different orientations. Hence, terms such as “below” and “above” are used for sake of explanation and should not be considered unduly limiting.

The body of tuning material 40 serves to remove surplus oxygen and/or other unwanted species (e.g., contaminates) from one or both of the channel material 30 and the gate dielectric material 32. The underlying principle of operation of the tuning material 40 may be known as gettering in some circumstances. Chemical species may be drawn to and bonded or otherwise retained by the tuning material 40.

Removal of surplus oxygen and/or other unwanted species (e.g., contaminates) may occur in a subregion of the body of channel material 30 when the body of channel material 30 is thick, which is considered useful despite the entire thickness of channel material 30 not necessarily being affected. When the body of channel material 30 is relatively thin, the entire thickness of channel material may have surplus oxygen and/or other unwanted species (e.g., contaminates) removed. Removal of surplus oxygen and/or other unwanted species (e.g., contaminates) from the body of gate dielectric material 32 follows the same principle, in that removal may occur in a subregion or the entire thickness of the body of gate dielectric material 32, depending on the thicknesses of the body of gate dielectric material 32 and the intervening body of channel material 30. In some examples, surplus oxygen and/or other unwanted species (e.g., contaminates) are only removed from the body of channel material 30.

The tuning material may include titanium, titanium silicide, titanium nitride, titanium oxide, titanium-tungsten alloy, tungsten, tungsten silicide, barium, zirconium, zirconium oxide, palladium, palladium oxide, platinum, platinum oxide, vanadium, tin, antimony, germanium, hafnium, and tantalum. Suitable alloys, nitrides, silicides, and/or oxides of such materials may be used. Any suitable combination of such materials may be used.

The thickness of the body of tuning material 40 should be sufficient to provide a suitable amount of tuning, but otherwise is not particularly limited. In various examples, the thickness of the body of tuning material 40 is between about 0.5 nm and about 10 nm.

The TFT 10 further includes a body of mediating material 42 positioned between the body of tuning material 40 and the bodies of source and drain material 24s, 24d and channel material 30. The body of mediating material 42 mediates the tuning effect of the body of tuning material 40. In this example, the body of mediating material 42 also prevents electrical shorting between the bodies of source and drain material 24s, 24d. Examples of suitable mediating materials include low-K dielectrics, high-K dielectrics, semiconductors, etc. The mediating material may be hafnium oxide, for example.

The material and thickness of the body of mediating material 42 should be selected to obtain a desired tuning effectiveness for the body of tuning material 40. If the thickness is too high, tuning effectiveness may be less than desired. If the thickness is too low, tuning may be too strong. In various examples, the thickness of the body of mediating material 42 may be between about 0.5 nm and about 20 nm.

In known TFTs with similar source/drain arrangements, the source and drain are disposed on a conventional substrate. In the example TFT 10 depicted in FIG. 1, the source and drain material 24s, 24d are instead disposed on the body of mediating material 42, which is a structure different to those known. In addition, an adhesion layer, such as a layer of titanium nitride, may be provided on the body of mediating material 42 to promote the adhesion of the bodies of source and drain material 24s, 24d to the body of mediating material 42.

The present inventors have determined that a significant factor leading to current carrying limitations in the body of oxide semiconductor channel material 30 and to reduced carrier mobility/current flow through a channel formed therein is the presence of surplus oxygen atoms and/or other undesired materials, such as nitrogen, carbon, chlorine, fluorine, etc. within the body of oxide semiconductor channel material 30. Such undesired materials can be general contaminates and/or can inadvertently be introduced during various manufacturing processes. In addition, the effectiveness of the gate dielectric material may be reduced by oxygen atoms and/or other undesired materials. Moreover, oxygen atoms and/or other undesired materials may move between the semiconductor channel material and the gate dielectric material, which may confound other techniques of stabilizing the characteristics of these materials.

For example, when the body of channel material 30 is selected to be tin oxide, the nominal stoichiometry for the desired crystalline structure of the oxide semiconductor material is 1:2 (i.e., one tin atom per two oxygen atoms). Defects occur in the body of channel material 30 when surplus oxygen atoms are present, increasing the stoichiometric ratio to 1:2.1, 1:2.2, etc., and these defects inhibit carrier mobility/current flow. Similarly, defects occur in the body of channel material 30 if undesired nitrogen, carbon, chlorine, fluorine, etc. atoms and/or other contaminates are introduced to the body of channel material 30 during manufacture or at other times.

The tuning material is advantageously selected to attract oxygen and/or other undesirable species through the mediating material and out of at least a region of the oxide material near the mediating material. Hence, in the above example, the body of tuning material 40 acts to promote the stoichiometry of the body of oxide semiconductor channel material 30 to be as close to the expected stoichiometric value as possible. This improves carrier mobility/current flow through the channel and may also extend the useful life of the TFT 10 by the same mechanism should undesirable species migrate into the channel material while the TFT 10 is in use.

Further, in various examples, the body of tuning material 40, being selected as a suitably electrically conductive material, may also serve to provide an electrical connection to one or more of the bodies of source, drain, and/or gate materials 24s, 24d, 34. The body of tuning material 40 may thus advantageously serve a dual purpose, i.e., tuning and electrical signal communication.

Manufacture of the TFT 10 may be performed using conventional BEOL, MOL, and/or Bside processes. One or more layers of TFTs 10 may be formed over one or more layers of other devices made using FEOL, MOL, BEOL, or Bside processes.

The manufacture of materials, layers, and/or features of semiconductor devices is referred to herein as “forming.” As will be apparent to those of ordinary skill in the art, unless otherwise mentioned, “forming” is intended to include all semiconductor manufacturing techniques suitable and applicable therefor including, without limitation, deposition (e.g., chemical vapor deposition or CVD, atomic layer deposition or ALD, physical vapor deposition or PVD, etc.), plasma-enhanced/assisted atomic layer deposition (PEALD/PAALD), thermal ALD (T-ALD), plasma-enhanced chemical vapor deposition (PECVD), sputtering, lithography/photolithography, etching, implantation, annealing, oxidation, and similar processes. While examples of specific types of forming are given below, it should be understood that comparable methods of forming may be alternatively or additionally used, unless otherwise mentioned, without departing from the present disclosure.

In one example method of manufacture, the body of tuning material 40 is sputtered onto the substrate 20, the body of mediating material 42 is deposited over the body of tuning material 40 using ALD, a layer of source/drain material is sputtered onto the body of mediating material 42, the layer of source/drain material is patterned (e.g., using lithographic etching) to form the separate bodies of source and drain material 24s, 24d with a gap therebetween exposing the substrate 20, the body of channel material 30 is deposited by ALD over the bodies of source and drain material 24s, 24d and in the gap therebetween over the substrate 20 using ALD, the body of gate dielectric material 32 is deposited by ALD over the body of channel material 30, and the body of gate material 34 is sputtered over the body of gate dielectric material 32. Additional patterning, such as by lithographic etching, may be used to shape layers and/or bodies of material.

In this example, annealing is performed as part of manufacture to cause the body of tuning material 40 to perform its tuning of the body of channel material 30 during manufacture. While some tuning may also occur over the operational life of the TFT 10, as may be dependent on operational temperature, annealing during manufacture increases the temperature of the TFT above what is normally expected during operation. Increased temperature accelerates the tuning effectiveness. Performing most or all of the tuning at manufacture results in a TFT 10 that has stable operational characteristics over its useful life. In other examples, when change in operating characteristics of the TFT 10 is tolerable over its useful life, annealing during manufacture may be reduced or omitted and most or all of the tuning may occur during operation. In still other examples, the relative proportions of tuning at manufacture to tuning during operation may be selected based on service requirements.

Annealing may be performed on the TFT 10 in the form shown in FIG. 1 (i.e., after forming the body of gate material 34). Alternatively or additionally, annealing may be performed at a later stage of manufacture. Alternatively or additionally, annealing may be performed immediately after the body of channel material 30 is formed.

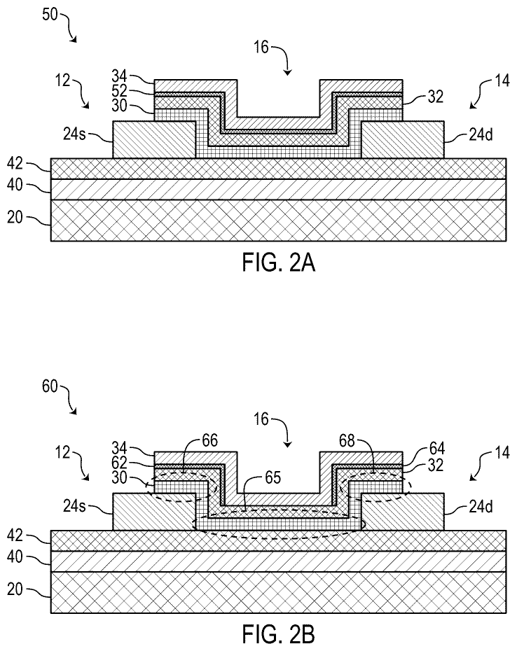

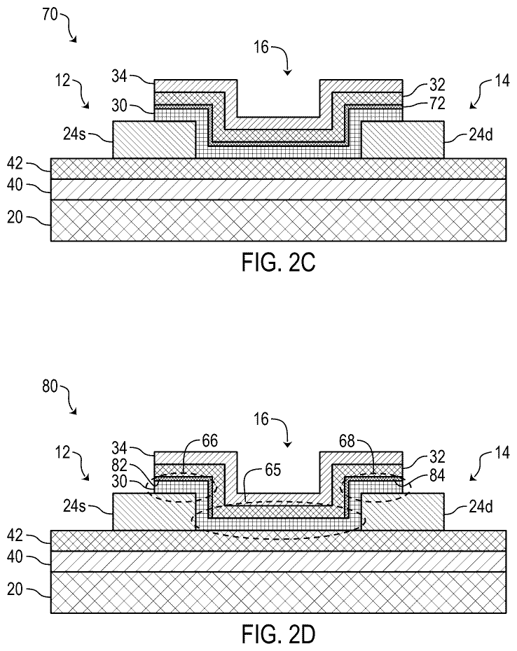

FIGS. 2A-2D show example TFTs 50, 60, 70, 80 with blocking material that is used to control tuning according to the present disclosure. The TFTs 50, 60, 70, 80 are similar to the TFT 10 and only differences will be discussed in detail. The above description may be referenced for details not repeated below. In addition, features and aspects of any two or more of the TFTs 10, 50, 60, 70, 80 may be combined to arrive at other TFTs that are within the scope of this disclosure.

While the usefulness of the tuning provided by the body of tuning material 40 has been discussed above, the body of gate material 34 may also perform tuning on one or both of the bodies of oxide semiconductor channel material 30 and gate dielectric material 32. This tuning by the gate material is in addition to tuning by the tuning material. Tuning by the gate material may be undesirable for various reasons, such as contaminating or undesirably changing the properties of the gate dielectric material 32, contaminating or undesirably the properties of the gate material, or over-tuning the channel or gate dielectric material to the point that the material has too much oxygen removed. Additional tuning by the body of gate material 34 may occur during an anneal used to effect the desired tuning by the body of tuning material 40. To reduce or eliminate undesired tuning by the gate material, blocking material may be used. Blocking material may be formed by introducing atoms, such as chlorine, fluorine, nitrogen, etc., to the channel material or the gate dielectric material. Alternatively, a separate layer of blocking material may be formed at or near the body of channel material 30 or the body of gate dielectric material 32.

Blocking material causes preferential tuning by the body of tuning material 40 over any tuning that may be caused by the body of gate material 34. While some tuning by the gate material may still occur, the purpose of the blocking material is to inhibit movement of oxygen or other species towards the gate material thereby creating a path of lower resistance towards the tuning material.

Forming of blocking material may be done by various treatments such as plasma, thermal, wet chemicals, etc. For example, nitrogen plasma may be applied to the body of channel material 30 or the body of gate dielectric material 32. Accordingly, a body of blocking material may include a plasma treated portion of the body of channel material 30 and/or the body of gate dielectric material 32.

FIG. 2A shows an example TFT 50 with blocking material. A body of blocking material 52 is provided between the body of gate dielectric material 32 and the body of gate material 34. The body of blocking material 52 may be formed as discussed above, for example, by plasma treating the body of gate dielectric material 32 after the body of gate dielectric material 32 is formed. In this example, the body of blocking material 52 is a layer that extends the entire length of the body of gate dielectric material 32 from the source 12 to the drain 14.

FIG. 2B shows another example TFT 60 with blocking material. Two bodies of blocking material 62, 64 are provided at different locations in the form of different regions of a layer that is positioned between the body of gate dielectric material 32 and the body of gate material 34. In this example, one body if blocking material 62 is proximate the source 12 and the other body of blocking material 64 is proximate the drain 14. Blocking material at different locations can be formed simultaneously or separately. Together the bodies of blocking material 62, 64 do not extend the entire length of the body of channel material 30. In other words, a gap exists between the bodies of blocking material 62, 64. The bodies of blocking material 62, 64 may be formed as discussed above, for example, by plasma treating the body of gate dielectric material 32 after the body of gate dielectric material 32 is formed.

In this example, a first body of blocking material 62 is disposed near the source 12 at a location where a portion 66 of the body of channel material 30 is further from the body of tuning material 40 compared to the central portion 65 of channel material, which is closer to the body of tuning material 40. Similarly, a second body of blocking material 64 is disposed near the drain 14 at a location where a portion 68 of the body of channel material 30 is further from the body of tuning material 40 compared to the central portion 65 of channel material, which is closer to the body of tuning material 40. As such, the bodies of blocking material 62, 64 inhibit, at least to some degree, tuning by the body of gate material 34 at locations where the influence of the gate material 34 is greatest relative to influence of the tuning material 40, thereby increasing the preference for tuning by the body of tuning material 40. At the same time, the absence of blocking material at the central portion 65 of body of channel material 30 helps maintain the expected formation of the carrier channel during operation of the TFT 60. This principle of blocking a certain region to cause preferential tuning by the tuning material 40, compared to the gate material 34, similarly applies to tuning of the body of gate dielectric material 32.

FIG. 2C shows another example TFT 70 with blocking material. A body of blocking material 72 is provided between the body of channel material 30 and the body of gate dielectric material 32. The body of blocking material 72 may be formed as discussed above, for example, by plasma treating the body of channel material 30 after the body of channel material 30 is formed. In this example, the body of blocking material 72 is a layer that extends the entire length of the body of channel material 30 from the source 12 to the drain 14. In this example, the body of blocking material 72 causes the body of channel material 30 to be preferentially tuned by the tuning material 40 and causes the body of gate dielectric material 32 to be preferentially tuned by the body of gate material 34.

FIG. 2D shows another example TFT 80 with blocking material. Two bodies of blocking material 82, 84 are provided at different locations in the form of different regions of a layer that is positioned between the body of channel material 30 and the body of gate dielectric material 32. The blocking material at different locations may be formed simultaneously or separately. Together the bodies of blocking material 82, 84 do not extend the entire length of the body of channel material 30. The bodies of blocking material 82, 84 may be formed as discussed above, for example, by plasma treating the body of channel material 30 after the body of channel material 30 is formed.

In this example, a first body of blocking material 82 is disposed near the source 12 at a location where a portion 66 of the body of channel material 30 is further from the body of tuning material 40 compared to the central portion 65 of channel material, which is closer to the body of tuning material 40. Similarly, a second body of blocking material 84 is disposed near the drain 14 at a location where a portion 68 of the body of channel material 30 is further from the body of tuning material 40 compared to the central portion 65 of channel material, which is closer to the body of tuning material 40. As such, the bodies of blocking material 82, 84 inhibit, at least to some degree, tuning of the channel material 30 by the body of gate material 34 at locations where the influence of the gate material 34 is greatest, thereby increasing the preference for tuning of the channel material 30 by the body of tuning material 40. At the same time, the absence of blocking material at the central portion 65 of body of channel material 30 helps maintain the expected formation of the carrier channel during operation of the TFT 60.

Conversely, the bodies of blocking material 82, 84 inhibit, at least to some degree, tuning of the gate dielectric material 32 by the body of tuning material 40 proximate to the bodies of blocking material 82, 84, thereby increasing the preference for tuning of the gate dielectric material 32 by the gate material 34.

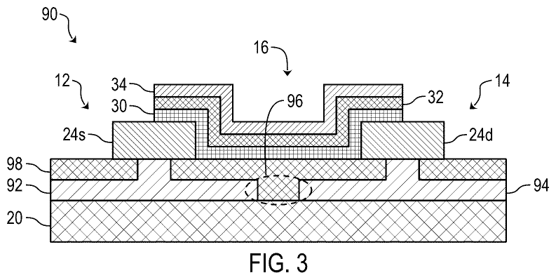

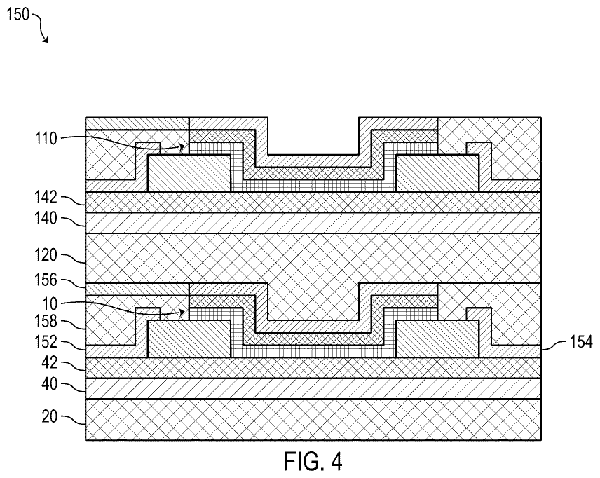

FIG. 3 shows an example thin-film transistor 90 with tuning material used as conductors according to the present disclosure. The TFT 90 is similar to the TFT 10 and only differences will be discussed in detail. The above description may be referenced for details not repeated below.

The TFT 90 includes bodies of tuning material 92, 94 positioned and patterned to act as electrical connections to the source 12 and drain 14. The bodies of tuning material 92, 94 are selected to be made from suitably electrically conductive material and thus are useable to communicate electrical signals to/from the source 12 and drain 14. The bodies of tuning material 92, 94 may be wiring that takes the form of metal wires and/or vias.

A first body of tuning material 92 is in electrical contact with the body of source material 24s, and a second body of tuning material 94 is in electrical contact with the body of drain material 24d. The bodies of tuning material 92, 94 are spaced apart, for example, by a gap 96, to avoid electrical shorting.

The TFT 90 further includes mediating material 98 that serves the same function as mediating material discussed above. The mediating material 98 is formed over the bodies of tuning material 92, 94 except for the points of contact with the bodies of source/drain material 24s, 24d. The mediating material 98 may further serve to electrically isolate the bodies of tuning material 92, 94 from one another at gap 96, which is filled with mediating material 98.

In this example, the tuning material serves the dual purpose of tuning and conducting electrical signals. Accordingly, the tuning material should be selected so that its change in properties, if any, after and/or during tuning does not unduly inhibit its ability to conduct current.

Regarding the various examples discussed above, features and aspects of any two or more of the example TFTs 10, 50, 60, 70, 80, 90 may be combined without departing from the present disclosure. For example, the dual-purpose bodies of tuning material 92, 94 may be used with localized bodies of blocking material 62, 64, 82, 84.

FIG. 4 shows an example stacked structure 150 of TFTs with tuning material according to the present disclosure. In this example, each TFT 10, 110 of the stacked structure 150 is substantially the same as the TFT 10 of FIG. 1. The above description may be referenced for details not repeated below. In other examples, the stacked structure 150 may use different TFT structures, such as the TFTs 50, 60, 70, 80, 90.

In addition to the structure shown in FIG. 1, the TFT 10 is shown as including a source electrode (lead, connector, metal trace, etc.) 152 connected to the body of source material 24s, a drain electrode 154 connected to the body of drain material 24d, and a gate electrode 156 connected to the body of gate material 34, which facilitate operation of the TFT 10. The electrodes 152, 154, 156 may have various arrangements different from that depicted.

Bodies of tuning material 40 and mediating material 42 provide tuning to the TFT 10, as discussed above.

An insulative or dielectric material 158, such as ILD, is provided to electrically isolate the source/drain electrodes 152, 154 and gate electrode 156. The material 158 may be selected as a material given above for the substrate 20, for example.

Additional material 120, such as ILD, may be disposed over the TFT 10 to act as a substrate for an additional TFT 110, which may be similar or identical to the TFT 10 or, in other examples, a TFT 50, 60, 70, 80, 90. This additional substrate 120 may be made of a material given above for the substrate 20, for example. The TFT 110 has a similar or identical type of electrical connection as the TFT 10. In various examples (not depicted), the TFT 110 is electrically connected to the TFT 10, in that one or more of a source, drain, and/or gate of the TFT 110 may be electrically connected to one or more of a source, drain, and/or gate of the TFT 10 using wiring, such as metal wires and/or vias.

An additional body of tuning material 140 and an additional body of mediating material 142 may be provided over the substrate 120, and these may be similar or identical to the bodies of tuning material 40 and mediating material 42 discussed above. The bodies of tuning material 140 and mediating material 142 provide tuning to the TFT 110 much like the bodies of tuning material 40 and mediating material 42 provide tuning to the TFT 10.

The stack structure 150 may have any suitable number of layers of TFTs 10, 110 with tuning material.

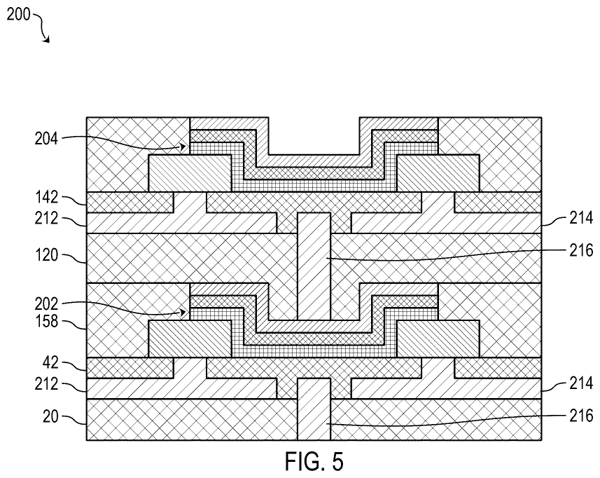

FIG. 5 shows an example stacked structure 200 of TFTs with tuning material and electrical connections according to the present disclosure. In this example, each TFT 202, 204 of the stacked structure 200 is substantially the same as the TFT 10 of FIG. 1. The above description, particularly that related to FIG. 4, may be referenced for details not repeated below. In other examples, the stacked structure 200 may use different TFT structures, such as the TFTs 50, 60, 70, 80, 90.

Bodies of tuning material 212, 214, 216 are positioned between respective mediating material 42, 142 and respective substrate 20, 120. Bodies of tuning material 212, 214, 216 are formed with suitable geometry to provide electrical connections to the source 12, drain 14, and gate 16, respectively, of each TFT 202, 204.

Bodies of tuning material 212, 214, 216 should be mutually electrically isolated to prevent shorting and should also be provided with a suitable size and geometry to perform the desired tuning of the channel material 30. In example depicted, respective bodies of tuning material 212, 214 connect to the source and drain 12, 14 of the upper TFT 204, while the nearby central body of tuning material 216 connects to the gate 16 of the lower TFT 202. As such, a layer of tuning material may simultaneously provide electrical connections to different layers of TFTs 202, 204.

Bodies of tuning material 212, 214, 216 may be formed by lithography and etching of sputtered material as well as by via forming techniques.

In view of the above, it should be apparent that a TFT or stack thereof may have its characteristics tuned by the addition of tuning material. Tuning material may be configured to remove surplus oxygen and/or other unwanted species (e.g., contaminates) from material of the TFT, such as semiconductor channel material and gate dielectric material. Blocking material may be used to apply preferential tuning to a particular material or region thereof. As such, the current carrying capacity and useful operational life of the TFT may be improved.

In the above description, auxiliary verbs “can” and “may” are used interchangeably herein to denote components, features, and/or aspects of the present disclosure that are capable, configurable, selectable, modifiable, or optional, as would be apparent to one of ordinary skill in the art given the benefit of this disclosure. These terms should not be taken as limiting the present disclosure, unless otherwise specified.

Spatial prepositions, such as “over”, “under”, “on”, “above”, “below”, “up”, “down”, “beside”, etc., are provided for sake of explanation and should not be taken as limiting the present disclosure to an absolute spatial orientation or arrangement, unless otherwise specified. For example, one of ordinary skill in the art would understand that a first element is above or below a second element depending on the perspective of the observer.

The articles “a”, “an”, “the”, “said”, etc. indicate singular and plural, unless otherwise specified.

The conjunction “or” is used inclusively and should be understood to mean “and/or”, unless otherwise specified.

Sets of elements A, B, C described as A, B, or C; A, B, and C; A, B, and/or C; or A, B, C should be considered open sets from which one or more elements or a combination of one or more elements may be selected, unless otherwise specified. Sets of elements are open, unless specified to be closed, for example, by use of the term “consist”, “consisting”, or similar closed language.

The above clarifications apply to both the specification and claims.

The figures are not to scale, unless otherwise specified.

The above-described embodiments of the invention are intended to be examples of the present disclosure and alterations and modifications may be effected thereto, by those of ordinary skill in the art, without departing from the scope of the invention which is defined solely by the claims appended hereto.

1. A thin-film transistor comprising:
a substrate;
a source including a body of source material over the substrate;
a drain including a body of drain material over the substrate;
a body of channel material between the source and the drain, wherein the channel material is an oxide semiconductor;
a body of gate dielectric material on the body of channel material;
a body of gate material on the body of gate dielectric material; and
a body of tuning material between the substrate and the body of channel material, the body of tuning material to remove undesirable chemical species from the body of channel material, the body of gate dielectric material, or both the body of channel material and the body of gate dielectric material.

2. The thin-film transistor of claim 1, further comprising a body of dielectric mediating material between the body of tuning material and the body of channel material.

3. The thin-film transistor of claim 1, wherein the body of tuning material is in electrical contact with the body of source material.

4. The thin-film transistor of claim 3, wherein the body of tuning material is a first body of tuning material, the thin-film transistor further comprising a second body of tuning material in electrical contact with the body of drain material.

5. The thin-film transistor of claim 1, further comprising a body of blocking material to inhibit tuning by the body of gate material.

6. The thin-film transistor of claim 5, wherein the body of blocking material is positioned between the body of gate dielectric material and the body of gate material.

7. The thin-film transistor of claim 5, wherein the body of blocking material is positioned between the body of channel material and the body of gate dielectric material.

8. The thin-film transistor of claim 5, wherein the body of blocking material extends an entire length of the body of channel material.

9. The thin-film transistor of claim 5, wherein the body of blocking material is a first body of blocking material, the thin-film transistor further comprising a second body of blocking material positioned at a location different from the first body of blocking material to inhibit tuning by the body of gate material.

10. The thin-film transistor of claim 5, wherein the body of blocking material comprises a plasma treated portion of the body of gate dielectric material.

11. The thin-film transistor of claim 5, wherein the body of blocking material comprises a plasma treated portion of the body of channel material.

12. The thin-film transistor of claim 5, wherein the body of blocking material is positioned at a location where the body of channel material is closer to the body of gate material than to the body of tuning material.

13. The thin-film transistor of claim 1, wherein the undesirable chemical species comprises oxygen.

14. The thin-film transistor of claim 1, wherein the tuning material is titanium.

15. A method of manufacturing a thin-film transistor, the method comprising:
forming a body of tuning material over a substrate;
forming a source including a body of source material over the body of tuning material;
forming a drain including a body of drain material over the body of tuning material;
forming a body of channel material between the source and the drain, wherein the channel material is an oxide semiconductor;
forming a body of gate dielectric material on the body of channel material;
forming a body of gate material on the body of gate dielectric material; and
wherein the body of tuning material removes undesirable chemical species from the body of channel material, the body of gate dielectric material, or both the body of channel material and the body of gate dielectric material.

16. The method of claim 15, further comprising forming a body of dielectric mediating material on the body of tuning material.

17. The method of claim 15, further comprising forming a body of blocking material to inhibit tuning by the body of gate material.

18. The method of claim 17, further comprising forming multiple bodies of blocking material to inhibit tuning of multiple regions of the body of channel material, the body of gate dielectric material, or both the body of channel material and the body of gate dielectric material.

19. The method of claim 15, wherein the undesirable chemical species comprises oxygen.

20. The method of claim 15, wherein the tuning material is titanium.
